(19) United States
(12) Patent Application Publication
(10) Pub. No.: US 2025/0376766 A1
(43) Pub. Date: Dec. 11, 2025

(54) VAPOR DEPOSITION CHAMBER WITH IN-SITU FLOW CONDUCTANCE OPTIMIZATION

(71) Applicant: Applied Materials, Inc., Santa Clara, CA (US)

(72) Inventors: Muhannad Mustafa, Milpitas, CA (US); Srinivas Gandikota, Santa Clara, CA (US); Alexander Jansen, Danville, CA (US); Muhammad M. Rasheed, San Jose, CA (US)

(73) Assignee: Applied Materials, Inc., Santa Clara, CA (US)

(21) Appl. No.: 18/772,974

(22) Filed: Jul. 15, 2024

Related U.S. Application Data
(60) Provisional application No. 63/656,781, filed on Jun. 6, 2024.

(51) Int. Cl. C23C 16/455; C23C 16/458

(52) U.S. Cl. CPC C23C 16/4558; C23C 16/4584

(57) ABSTRACT

Substrate processing chamber gas distribution assemblies and methods utilizing of processing substrates using the same are described. The gas distribution assembly includes an edge ring having a plurality of edge ring openings disposed on the outer peripheral portion and an inner pumping liner including a pumping liner wall concentric with the edge ring and an outer pumping liner wall, the inner pumping liner wall and the outer pumping liner wall defining a pumping liner, the inner pumping liner wall having a plurality of inner pumping liner wall openings. Rotation of the edge ring provides in situ flow conductance through the pumping liner.

### CROSS-REFERENCE TO RELATED APPLICATIONS

This application claims priority to U.S. provisional application Ser. No. 63/656,781, filed on Jun. 6, 2024, the entire disclosure of which is incorporated by reference herein.

### TECHNICAL FIELD

Embodiments of the present disclosure pertain to the field of electronic device manufacturing. In particular, embodiments of the disclosure are directed to substrate processing chambers including processing chamber exhaust systems and methods of controlling flow conductance of gas through a pumping liner of a substrate processing chamber.

### BACKGROUND

Microelectronic device manufacture includes the deposition of thin films of material in substrate processing chambers configured to performing various deposition, etch, and thermal processes, among other processes, upon substrates, such as silicon (Si) wafers, gallium arsenide (GaAs) wafers, glass, sapphire, and the like. Various etch processes and deposition processes, including chemical vapor deposition (CVD) and atomic layer deposition (ALD), can be optimized by controlling the process conditions within the substrate processing chamber. In particular, during a deposition process, the chemical reaction rate is impacted by processing chamber pressure as gas flow. As such, the ability to transition between and maintain precise target pressures within the substrate processing chamber is important to forming uniform deposition of thin films during semiconductor device fabrication.

One method of controlling pressure within a substrate processing chamber utilizes a pumping liner disposed within the substrate processing chamber. However, a pumping liners is a fixed piece of hardware and does not provide in-situ modification of flow conductance of gas though the pumping liner. Another method of controlling pressure within a substrate processing chamber uses vacuum pressure, in which an exhaust line extends from the substrate processing chamber to a vacuum pump, and a throttle valve is disposed along the exhaust line. The throttle valve is opened and closed to varying degrees to adjust pressure within the substrate processing chamber. While such systems provide adjustable pressure, they provide limited pressure tunability.

Accordingly, there is a need in the art for improved substrate processing chamber and methods that allow for a wider range of pressures at which semiconductor processing chambers can operate. There is a further need for improved substrate processing chambers and methods that provide a more precise transition between different pressures and maintain precise target pressures during various stages of a semiconductor fabrication process. Additionally, it would be desirable to provide is to in-situ adjustability of flow conductance through the pumping liner during CVD and ALD processes.

### SUMMARY

A first aspect of the disclosure pertains to a substrate processing chamber gas distribution assembly. In one or more embodiments, the gas distribution assembly comprises a gas manifold having an inner gas channel that extends along a central axis of the gas manifold, the inner gas channel having an upper portion and a lower portion; a backing plate coupled to the gas manifold and having a contoured bottom surface that extends downwardly and outwardly from a central opening coupled to the lower portion of the inner gas channel to a peripheral portion of the backing plate; a gas distribution faceplate disposed below the backing plate, having a top surface and a bottom surface with a plurality of apertures extending through the gas distribution faceplate from the top surface to the bottom surface; a rotatable pedestal disposed beneath the gas distribution faceplate and configured to support a substrate, the rotatable pedestal having an outer peripheral portion; an edge ring disposed on the outer peripheral portion of the rotatable pedestal and configured to be rotated with the rotatable pedestal and having a plurality of edge ring openings; and an inner pumping liner wall concentric with the edge ring and an outer pumping liner wall, the inner pumping liner wall and the outer pumping liner wall defining a pumping liner, the inner pumping liner wall having a plurality of inner pumping liner wall openings, wherein rotation of the edge ring varies a flow conductance through the pumping liner by varying a degree of alignment of at least a portion of the plurality of the edge ring openings and the plurality of inner pumping liner wall openings.

Another aspect of the disclosure pertains to a method of processing a substrate in a substrate processing chamber. In one or more embodiments, the method comprises placing a substrate on a rotatable pedestal disposed beneath a gas distribution faceplate of the substrate processing chamber, the rotatable pedestal having an outer peripheral portion and an edge ring having a plurality of edge ring openings disposed on the outer peripheral portion of the rotatable pedestal; flowing gas through an inner pumping liner including a pumping liner wall concentric with the edge ring and an outer pumping liner wall, the inner pumping liner wall and the outer pumping liner wall defining the pumping liner, the inner pumping liner wall having a plurality of inner pumping liner wall openings; and rotating the edge ring to vary a flow conductance of the gas through the pumping liner by varying a degree of alignment of at least a portion of the plurality of the edge openings and the plurality of inner pumping liner wall openings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a schematic cross-sectional view of a prior art substrate processing chamber including a gas distribution assembly;

FIG. 2 depicts a schematic cross-sectional view of a substrate processing chamber in accordance with one or more embodiments of the disclosure;

FIG. 3A shows an isometric view of an edge ring in accordance with one or more embodiments of the disclosure;

FIG. 3B shows a partial cross-sectional view of the edge ring shown in FIG. 3A;

FIG. 3C shows a partial cross-sectional view the substrate processing chamber shown in FIG. 2;

FIG. 4A shows a partial cross-sectional view of the of the edge ring in a full conductance position;

FIG. 4B shows a partial cross-sectional view of the of the edge ring in a rotated 0.5 degrees with respect to the full conductance position in FIG. 4A;

FIG. 4C shows a partial cross-sectional view of the of the edge ring in a rotated 1 degree with respect to the full conductance position in FIG. 4A;

FIG. 4D shows a partial cross-sectional view of the of the edge ring in a rotated 1.5 degree with respect to the full conductance position in FIG. 4A;

FIG. 5 depicts a schematic partial cross-sectional view of a gas distribution assembly in accordance with one or more embodiments of the disclosure;

FIG. 6 shows an enlarged schematic view depicting partial overlap of an edge ring opening and an inner pumping liner opening in accordance with one or more embodiments of the disclosure;

FIG. 7 shows an enlarged schematic view depicting partial overlap of a plurality of edge ring openings and a plurality of inner pumping liner opening in accordance with one or more embodiments of the disclosure; and

FIG. 8 shows a flowchart depicting a method in accordance with one or more embodiment of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

According to one or more embodiments, when an element or structure is referred to as being “configured to” perform a particular function, or “made to” or “designed to” perform that function, however, when the Specification makes clear that the recited structure is “designed to” or “constructed to” perform that function, the element or structure is designed, made or configured to accomplish the specific objective.

Some embodiments of the present disclosure provide apparatus and methods that may be used to form film in substrate processing chambers, such as chemical vapor deposition (CVD) chamber, and to deposit materials during, for example, an CVD process. Some embodiments of the present disclosure provide apparatus and methods that may be used to form film in substrate processing chambers, such as an atomic layer deposition (ALD) chamber, and to deposit materials during, for example, an ALD process. Embodiments include substrate processing chambers and gas delivery systems which may include a remote plasma source and a gas distribution faceplate. The following substrate processing chamber description is provided for context and exemplary purposes, and should not be interpreted or construed as limiting the scope of the disclosure.

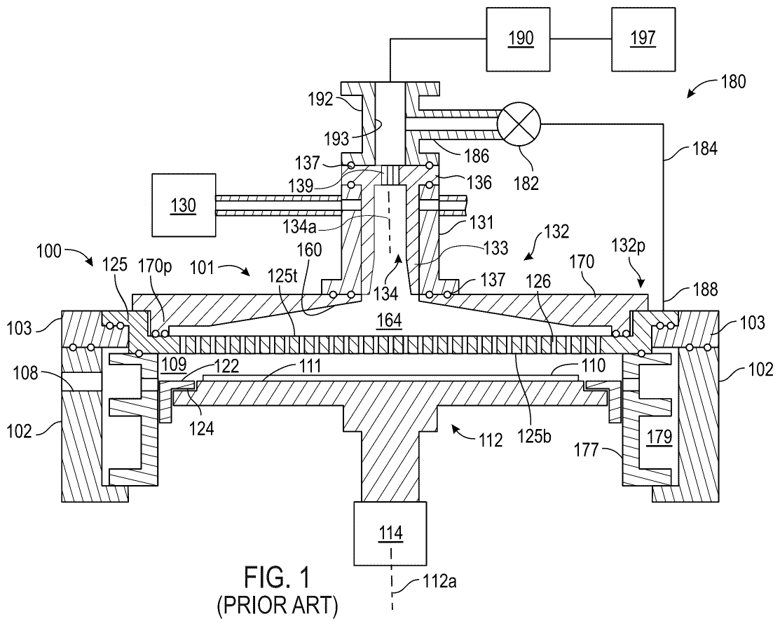

FIG. 1 is a schematic view of a substrate processing chamber 100 including a gas delivery system 130 configured for delivery of process gases to the substrate processing chamber 100 during CVD or ALD processes in accordance with one or more embodiments of the present disclosure. The substrate processing chamber 100 includes a chamber body 102 and a top wall 103 defining a processing volume 109 within the chamber body 102 and disposed below a chamber lid assembly 132. A slit valve 108 in the chamber body 102 provides access for a robot (not shown) to deliver and retrieve a substrate 110, such as a 200 mm or 300 mm semiconductor wafer or a glass substrate, to and from the processing volume 109 of the substrate processing chamber 100. A chamber liner 177 is disposed between the processing volume 109 and the chamber body 102 of the substrate processing chamber 100 to protect the chamber from corrosive gases used during processing/cleaning.

A pedestal 112 supports the substrate 110 on a substrate receiving surface 111 in the substrate processing chamber 100. In some embodiments, the pedestal 112 is rotatable and the rotatable pedestal is rotated by a rotating motor 114 configured to rotate the pedestal 112 and the substrate 110 disposed on the pedestal 112. In some embodiments, the substrate processing chamber comprises a lift motor (not shown), a lift plate (not shown), connected to the lift motor, which are mounted in the substrate processing chamber 100 and configured to raise and lower lift pins (not shown) movably disposed through the pedestal 112. The lift pins raise and lower the substrate 110 over the surface of the pedestal 112. The pedestal 112 may include a vacuum chuck (not shown), an electrostatic chuck (not shown), or a clamp ring (not shown) configured to hold the substrate 110 on the pedestal 112 during a CVD or ALD deposition process used to form a film on the substrate.

The temperature of the pedestal 112 may be adjusted to control the temperature of the substrate 110. For example, the pedestal 112 may be heated using an embedded heating element, such as a resistive heater (not shown), or may be heated using radiant heat, such as heating lamps (not shown) disposed above the pedestal 112. A purge ring 122 may be disposed on the pedestal 112 to define a purge channel 124, which provides a purge gas to a peripheral portion of the substrate 110 to prevent deposition on the peripheral portion of the substrate 110.

The gas delivery system 130 is positioned above the chamber body 102 and configured to supply a gas, such as a process gas and/or a purge gas, to the substrate processing chamber 100. A vacuum system (not shown) is in communication with a pumping liner 179 to evacuate gases from the substrate processing chamber 100 and to help maintain a target pressure or pressure range inside the substrate processing chamber 100.

In some embodiments, the substrate processing chamber comprises a substrate processing chamber gas distribution assembly 101, which includes a chamber lid assembly 132. The chamber lid assembly 132 includes an inner gas channel 134 defined by a gas insert 133 extending through a central portion of the chamber lid assembly 132. As shown in FIG. 1, the inner gas channel 134 extends perpendicularly toward the substrate receiving surface 111 of the pedestal 112 and also extends along a central axis 134a of the inner gas channel 134, through backing plate 170, and to a contoured bottom surface 160 of the backing plate 170. The central axis of the inner gas channel is aligned with the central axis 112a of the pedestal 112 upon which the substrate 110 is centered during an ALD or CVD process. A problem with existing CVD and ALD processes is that the flow is asymmetric with respect to the central axis 112a and with respect to the substrate 110. In some embodiments, an upper portion of the inner gas channel 134 is substantially cylindrical along central axis 134a and a lower portion of the inner gas channel 134 tapers away from the central axis 134a. The bottom surface 160 is sized and shaped to substantially cover the substrate 110 disposed on the substrate receiving surface 111 of the pedestal 112. The bottom surface 160 tapers from an outer edge of the backing plate 170 towards the inner gas channel 134. The gas delivery system 130 is configured to supply one or more gasses to the inner gas channel 134 during processing of the substrate 110 during a CVD or ALD process. In some embodiments, the gas delivery system 130 is coupled to the inner gas channel 134 via a single gas inlet. In some embodiments not shown, the gas delivery system 130 is coupled to the inner gas channel 134 via a plurality of gas inlets configured to supply different process gases, a purge gas, and other gases used during a CVD or ALD process.

A portion of bottom surface 160 of chamber lid assembly 132 may be contoured or angled downwardly and outwardly from a central opening coupled to the inner gas channel 134 to a peripheral portion 132p of chamber lid assembly 132 to help provide an improved velocity profile of a gas flow from inner gas channel 134 across the surface of substrate 110 (i.e., from the center of the substrate to the edge of the substrate). Bottom surface 160 may contain one or more surfaces, such as a straight surface, a concave surface, a convex surface, or combinations thereof. In one embodiment, bottom surface 160 is convexly funnel-shaped.

In one example, bottom surface 160 is downwardly and outwardly sloping toward an edge of the substrate receiving surface 111 to help reduce the variation in the velocity of the process gases traveling between bottom surface 160 of chamber lid assembly 132 and substrate 110 while assisting to provide uniform exposure of the surface of substrate 110 to a reactant gas. The components and parts of chamber lid assembly 132 may contain materials such as stainless steel, aluminum, nickel-plated aluminum, nickel, alloys thereof, or other suitable materials. In one embodiment, backing plate 170 may be independently fabricated, machined, forged, or otherwise made from a metal, such as aluminum, an aluminum alloy, steel, stainless steel, alloys thereof, or combinations thereof.

In some embodiments, the inner gas channel 134 and bottom surface 160 of the chamber lid assembly 132 may contain a mirror polished surface to help a flow of a gas along inner gas channel 134 and bottom surface 160 of chamber lid assembly 132.

The substrate processing chamber 100 further includes a gas distribution faceplate 125 having a plurality of apertures 126 disposed through the gas distribution faceplate 125. The gas distribution faceplate 125 is in fluid communication with the inner gas channel 134 such that a gas pathway from the inner gas channel 134 to the substrate is through the plurality of apertures 126 of the gas distribution faceplate 125. The gas distribution faceplate 125 advantageously creates a choked flow of gas through the gas distribution faceplate 125 resulting in a more uniform deposition on the substrate 110.

The upper portion of the inner gas channel 134 is defined by the gas insert 133 disposed in an inner region of a gas manifold 131. The gas insert 133 includes a cap 136 at an upper portion of the gas insert 133 and a central passageway that at least partially defines the inner gas channel 134 of the gas manifold 131. The cap 136 extends over the gas manifold 131 to hold the gas insert 133 in place. The gas insert 133 and the cap 136 include a plurality of o-rings 137 disposed between the gas insert 133 and the gas manifold 131 to ensure proper sealing. In some embodiments, the gas insert 133 includes a plurality of circumferential apertures (nots shown) which, when the gas insert 133 is inserted into the gas manifold 131, form a corresponding plurality of circumferential channels (not shown). The plurality of circumferential channels are fluidly coupled to the inner gas channel 134 via a corresponding plurality of cap openings 139 in the cap 136.

In some embodiments, the gas distribution faceplate 125 is formed of a non-corrosive ceramic material such as, for example, aluminum oxide or aluminum nitride. In some embodiments, each of the plurality of apertures 126 may have an equivalent fluid conductance. In some embodiments, a density of the plurality of apertures 126 (e.g., the number of apertures or the size of the openings of the apertures per unit area) may vary across the gas distribution faceplate 125 to achieve a deposition profile on the substrate 110. For example, a higher density of apertures 126 may be disposed at a center of the gas distribution faceplate 125 to increase the deposition rate at the center of the substrate relative to the edge of the substrate to further improve deposition uniformity. Although the plurality of apertures 126 are depicted as cylindrical through holes, the plurality of apertures 126 may have different profiles.

In some embodiments, the substrate processing chamber includes a remote plasma source (RPS) 190, an isolation collar 192 coupled to the RPS 190 at one end and the cap 136 at an opposite end, and a heater plate (not shown) coupled to an upper surface of the backing plate 170 circumferentially surrounding the gas manifold 131. The heater plate may be formed of stainless steel and include a plurality of resistive heating elements dispersed throughout the plate. A cleaning gas (i.e., purge gas) source 197 is fluidly coupled to the RPS 190. The cleaning gas source may include any gas suitable for forming a plasma to clean the substrate processing chamber 100. In some embodiments, for example, the cleaning gas may be nitrogen trifluoride (NF₃). The isolation collar 192 includes an inner channel 193 that is fluidly coupled to the inner gas channel 134 to flow a plasma from the RPS 190 through the inner gas channel 134 and into a reaction zone 164 above the gas distribution faceplate 125.

Typically, a cleaning gas is flowed through the inner gas channel 134 and the reaction zone 164 after a first gas is provided to the inner gas channel 134 by the gas delivery system 130 to quickly purge the first gas from the inner gas channel 134 and the reaction zone 164. Subsequently, a second gas is provided by the gas delivery system 130 to the inner gas channel 134 and the cleaning gas is again flowed through the inner gas channel 134 to the reaction zone 164 to quickly purge the second gas from the inner gas channel 134 and the reaction zone 164.

However, the gas distribution faceplate 125 tends to choke the flow of the cleaning gas to the pumping liner 179 and prolongs the cleaning process. An exhaust system 180 having an exhaust conduit 184 coupled to the isolation collar 192 at a first end 186 and to the pumping liner 179 at a second end 188. A valve 182 connected to exhaust conduit 184 is configured to selectively establish fluid coupling of the exhaust conduit 184 to the inner channel 193. In some embodiments, for example, the valve 182 may be a plunger type valve having a plunger that is moveable between a first to fluidly couple the exhaust conduit 184 to the inner channel 193 and a second position to seal off the exhaust conduit 184 from the inner channel 193. Each time the cleaning gas is flowed through the inner gas channel 134 and the reaction zone 164, the valve 182 is opened and the cleaning gas is rapidly exhausted to the pumping liner 179.

When a pressure inside of the substrate processing chamber 100 exceeds a pressure inside of the RPS 190, processing gasses may flow up to and damage the RPS 190. The plurality of cap openings 139 are configured to provide a choke point to prevent a backflow of processing gases from flowing up through the inner channel 193 and into the RPS 190. The isolation collar 192 may be formed of any material that is non-reactive with the cleaning gas being used. In some embodiments, the isolation collar 192 may be formed of aluminum when the cleaning gas is NF₃. In some embodiments, the isolation collar 192 and the gas insert 133 may be formed of aluminum and coated with a coating to prevent corrosion of the isolation collar 192 and the gas insert 133 from corrosive gases when used. For example, the coating may be formed of nickel or aluminum oxide.

In a substrate processing operation during a CVD or ALD process, a substrate 110 is delivered to the substrate processing chamber 100 through slit valve 108 by a robot (not shown). The substrate 110 is positioned on pedestal 112 through cooperation of lift pins (not shown) and the robot. The pedestal 112 raises substrate 110 into close opposition to a lower surface of the gas distribution faceplate 125. A first gas flow may be injected into inner gas channel 134 of the substrate processing chamber 100 by the gas delivery system 130 together or separately (i.e., pulses) with a second gas flow. The first gas flow may contain a continuous flow of a purge gas from a purge gas source and pulses of a reactant gas from a reactant gas source or may contain pulses of a reactant gas from the reactant gas source and pulses of a purge gas from the purge gas source. The second gas flow may contain a continuous flow of a purge gas from a purge gas source and pulses of a reactant gas from a reactant gas source or may contain pulses of a reactant gas from a reactant gas source and pulses of a purge gas from a purge gas source.

The gas flow travels through inner gas channel 134 and subsequently through the plurality of apertures 126 in the gas distribution faceplate 125. The gas is then deposited on the surface of the substrate 110. The bottom surface 160 of chamber lid assembly 132, which is downwardly sloping, is configured to reduce the variation of the velocity of the gas flow across the surface of gas distribution faceplate 125. Excess gas, by-products, etc. flow into the pumping liner 179 and are then exhausted from the substrate processing chamber 100. Throughout the processing operation, the heater plate circumferentially surrounding the gas manifold 131 may heat the chamber lid assembly 132 to a predetermined temperature to heat any solid byproducts that have accumulated on walls of the substrate processing chamber 100 (or a processing kit disposed in the chamber). As a result, any accumulated solid byproducts are vaporized. The vaporized byproducts are evacuated by a vacuum system (not shown) and pumping liner 179. In some embodiments, the predetermined temperature is greater than or equal to 150° C.

One or more embodiments of the edge ring, gas distribution assembly and substrate processing chamber including the edge ring and the gas distribution assembly described herein provides are configured to provide in-situ adjustability of flow conductance through the pumping liner during CVD or ALD processes performed in substrate processing chambers. This, in turn, results in uniform distribution of the precursor across the substrate surface and the formation uniform thin films. Non-uniform gas flow conductance through the pumping liner results in non-uniform film thickness across the substrate.

During CVD and ALD processes, uniform gas flow conductance through the pumping liner in the substrate processing chamber is needed to distribute the precursor uniformly across the substrate surface and to form uniform thin films. Non-uniform gas flow conductance through the pumping liner results in non-uniform film thickness across the substrate. In many substrate processing chambers configured for ALD and CVD, exhaust pumping and flow conductance is not axisymmetric through the substrate processing chamber. Accordingly, precursor gas flow is not symmetric about the central axis of the substrate being processed, and flow restriction is needed in the pumping liner to obtain better flow uniformity around the substrate during film deposition. On the other hand, greater flow and fast pumping through the flow liner is desired in some process steps as well as before moving the substrate from the pedestal. These two opposing requirements of flow restriction and greater flow at different stages of ALD and CVD processes drive a need for in-situ adjustment of gas flow conductance during ALD and CVD processes without breaking the vacuum environment in the substrate processing chamber. For an example, a CVD Si process needs high chamber pressure during film deposition but fast pumping before substrate transfer steps and purging steps during an ALD process.

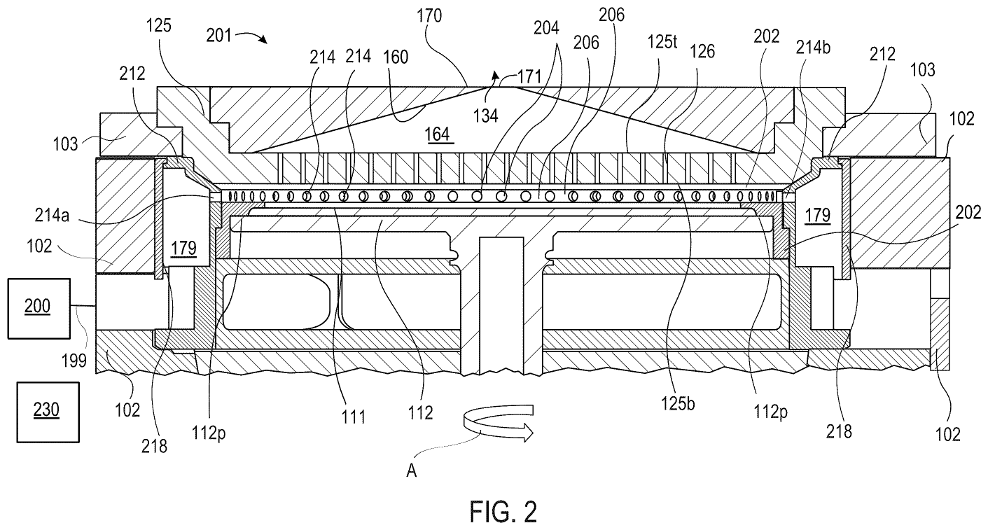

A first aspect of the disclosure pertains to a substrate processing chamber 100 including a substrate processing chamber gas distribution assembly 201 shown in FIG. 2. In FIG. 2, all of the components of substrate processing chamber 100 and the substrate processing chamber gas distribution assembly 101 shown in FIG. 1 are not repeated in FIG. 2. For example, in the embodiment shown in FIG. 2, the gas distribution assembly includes the chamber lid assembly 132, the gas manifold 131, the gas delivery system 130 and the gas distribution faceplate 125 as shown in FIG. 1. However, the present disclosure is not limited to the chamber lid assembly 132, the gas manifold 131, the gas delivery system 130, and the gas distribution faceplate 125 arrangement as shown in FIG. 1.

Thus FIG. 2 shows a portion of a substrate processing chamber to highlight the features that are configured to provide in situ adjustment of the gas flow conductance through the pumping liner 179. The substrate processing chamber gas distribution assembly 201 shown in FIG. 2 comprises a gas manifold 131 (as in FIG. 1) enclosing a gas insert 133 (FIG. 1), the gas manifold 131 having an inner gas channel 134 (FIG. 1) that extends along a central axis 134a of the gas manifold 131 (FIG. 1). The inner gas channel 134 has an upper portion and a lower portion. The gas flow assembly 201 has a backing plate 170 coupled to the gas manifold 131, and the backing plate 170 has a contoured bottom surface 160 that extends downwardly and outwardly from a central opening 171 coupled to the lower portion of the inner gas channel to a peripheral portion 170p of the backing plate 170.

As shown in both FIG. 1 and FIG. 2, a gas distribution faceplate 125 is disposed below the backing plate 170, having a top surface 125t and a bottom surface with a plurality of apertures 126 extending through the gas distribution faceplate 125 from the top surface 125t to the bottom surface 125b.

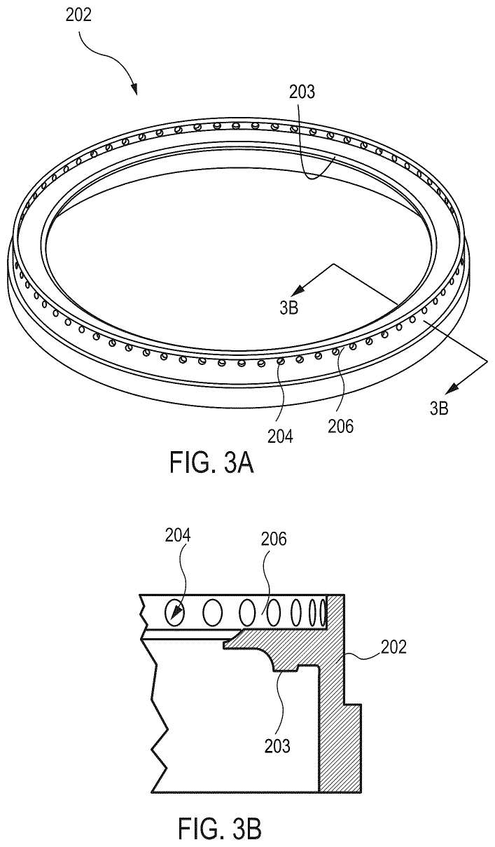

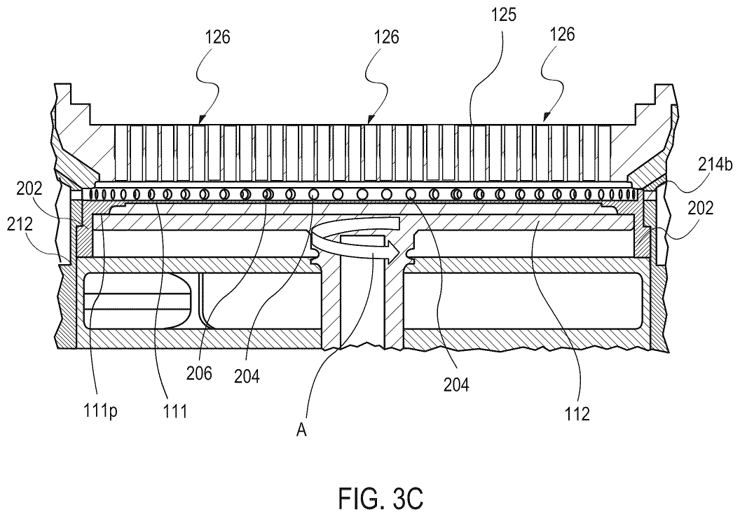

The features according to one or more embodiments of the disclosure that are configured to provide in situ adjustment of gas flow conductance through the pumping liner 179 will now be described. An edge ring 202 is supported on a rotatable pedestal 112 disposed beneath the gas distribution faceplate 125 and configured to support a substrate 110 (not shown in FIG. 2). The rotatable pedestal 112 has an outer peripheral portion 112p, and the edge ring 202 is disposed on the outer peripheral portion 112p of the rotatable pedestal 112 and is configured to be rotated with the rotatable pedestal 112. The edge ring 202 has a plurality of edge ring openings 204. As shown in FIGS. 3A-3C, the edge ring has a protrusion 203 or lip which rests upon the outer peripheral portion 112p of the rotatable pedestal 112.

In situ adjustment of gas flow through the pumping liner according to one or more embodiments is further enabled by a modified structure that forms the pumping liner 179. An inner pumping liner wall 212 is concentric with the edge ring 202. An outer pumping liner wall 218, which may be as separate component or integrally formed with the inner pumping liner wall 212 is spaced apart from the inner pumping liner wall 212. As shown in FIG. 2, the inner pumping liner wall 212 and the outer pumping liner wall 218 defining the pumping liner 179. As shown in FIG. 2, the edge ring 202 is supported on the outer peripheral portion 112p of the rotatable pedestal 112, which is rotated by a by a rotating motor 114 (shown in FIG. 1) configured to rotate the rotatable pedestal 112. In the arrangement shown, the edge ring 202 is coaxial with the inner pumping liner wall 212, and the inner pumping liner wall 212 has a plurality of inner pumping liner wall openings 214a, 214b.

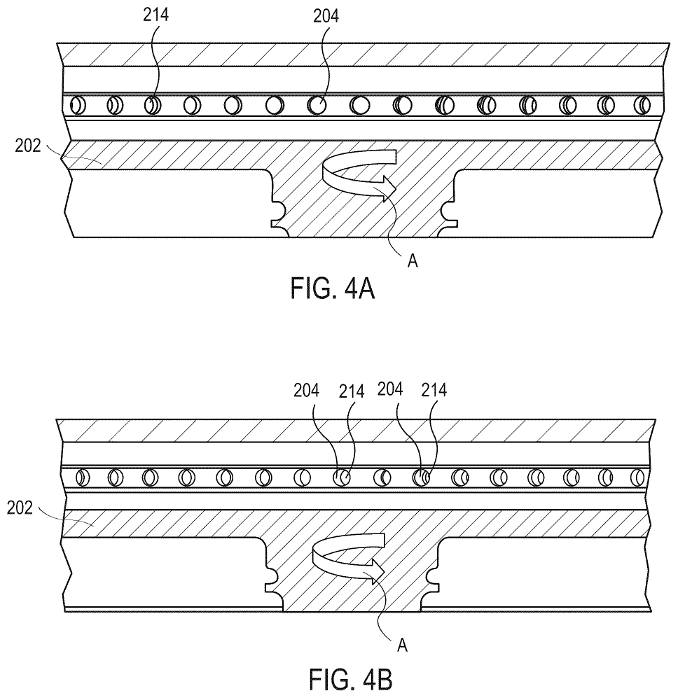

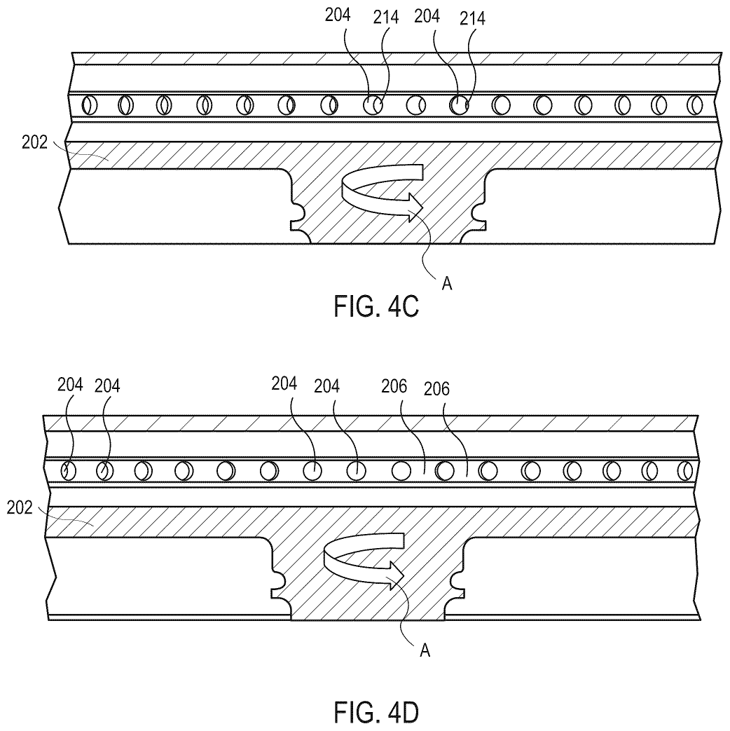

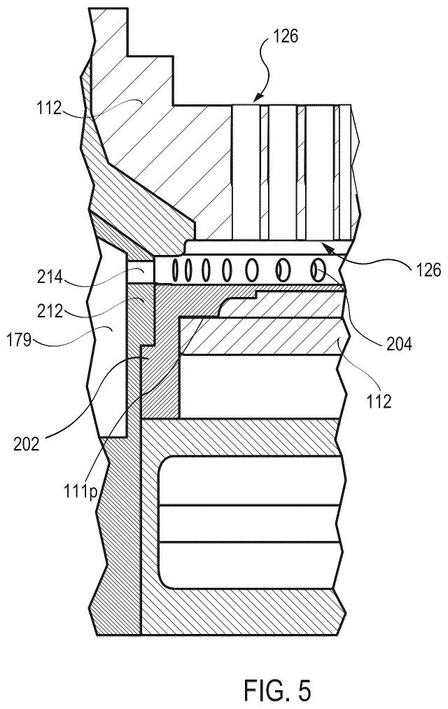

Rotation of the edge ring 202 with respect to the inner varies a gas flow conductance through the pumping liner 117 by varying a degree of alignment of at least a portion of the plurality of the edge ring openings 204 and the plurality of the inner pumping liner wall openings 212. Gas flows through the pumping liner 179 though an exhaust line 199 connected to a pump 200 in flow communication with the pumping liner 179. The edge ring 202 which is supported on the outer peripheral portion 112p of the rotatable pedestal 112 is rotated by the rotating motor 114. Gas flow through the pumping liner 179 is controlled by the pump 200 and a controller 230, which is configured to control the pump 200 and the degree of rotation of the rotatable pedestal 112. The rotatable pedestal 112 rotates in the direction of arrow A shown in FIGS. 2, 4, and 4A-D.

Rotation of the edge ring 202 relative to the inner pumping liner wall 212 adjusts the flow conductance of a gas flowing through the pumping liner 179 during a vapor deposition process. Relative rotation of the edge ring 202 and the inner pumping liner wall 212 also enables in-situ adjustment of flow conductance through the pumping liner 179 during a vapor deposition process. The in-situ adjustment of flow conductance through the In situ adjustment of flow conductance through the pumping liner 179 results in uniform distribution of the precursor across the substrate surface and the formation uniform thin films. Non-uniform gas flow conductance through the pumping liner results in non-uniform film thickness across the substrate.

According to one or more embodiments, there is a range of from about 24 to about 144 edge ring openings 204 and there is a range of from about 24 to about 144 inner pumping liner wall openings 214a, 214b in the inner pumping liner wall 212. The edge ring openings 204 and the inner pumping liner wall openings 214 according to one or more embodiments are evenly distributed around the edge ring 202 and the inner pumping liner wall 212. In one or more embodiments, the number of edge ring openings 204 and the inner pumping liner wall openings 214a, 214b are equal to each other. The edge ring openings 204 are separated by gaps 206 which are solid sections through which gas cannot pass through. While the edge ring openings 204 and the inner pumping liner wall openings 214a, 214b are shown as circular, the shape of these openings can be other than circular, for example rectangular slots, or any other suitably shaped opening.

In one particular embodiment, a first group the pumping liner wall openings 214a on one side adjacent to the pump 200 are a group of smaller openings, for example, circular openings as shown, and there is a pumping liner opening 214b on the opposite the pump in the form of an elongate slot (not shown). The elongate slot can be a single elongate slot that has the same area of opening of from four to twelve individual openings 214a on the side adjacent to the pump 200. In this particular embodiment the substrate processing chamber gas distribution assembly is configured to provide asymmetric flow conductance of gas with respect to a substrate processed on the pedestal. Thus according to a specific embodiment, on a first side of the inner pumping lining wall a first group of the plurality of inner pumping liner wall openings are spaced openings and on a second side opposite the first side of the inner pumping lining wall, there is an elongate slot configured to provide asymmetric flow conductance.

In a specific embodiment, there are 72 edge ring openings 204 and 72 inner pumping liner wall openings 214. Referring now to FIG. 4A, the edge ring 202 is in a full flow conductance position and the edge ring openings 204 and the inner pumping liner wall openings 214 are fully aligned so that there is maximum flow through the fully aligned edge ring openings 204 and the inner pumping liner wall openings 214.

The number of edge ring openings 204 and inner pumping liner wall openings 214 is used to determine the degrees of rotation the edge ring 202 is to be rotated to adjust the amount of flow conductance reduction when the edge ring 202 is rotated to a position in which the edge ring openings 204 are not fully aligned with the inner pumping liner wall openings 214. For example, the number of edge ring openings 204 and inner pumping liner wall openings 214 in some embodiments is selected so that the when the edge ring is rotated in increments of less than or equal to 10 degrees, less than or equal to 5 degrees, less than or equal to 4 degrees, less than or equal to 3 degrees, less than or equal to 2 degrees, less than or equal to one degree, or less than or equal to 0.5 degrees, the precision of flow conductance adjustment can be improved.

Referring now to FIG. 4B, when there are 72 edge ring 204 openings and 72 inner pumping liner wall openings 214, wherein the edge ring is configured to be rotated in increments of equal to or less than 2 degrees to adjust flow conductance through the pumping liner. In the embodiment shown, when the edge ring is rotated 0.5 degrees from the full flow conductance position of FIG. 4A, the flow conductance through the pumping liner reduced by 20% compared to the full conductance configuration shown in FIG. 4A. As can be seen in FIG. 4B, there is a small, partial misalignment of the edge ring openings 204 and the inner pumping liner wall openings 214 resulting in the flow conductance being 80% of full flow conductance.

FIG. 4C shows the edge ring 202 is rotated 1 degree from the full flow conductance position of FIG. 4A, and the flow conductance through the pumping liner reduced by 50% compared to the full flow conductance position shown in FIG. 4A, and there is zero flow conductance through the pumping liner 179. There is a greater degree of misalignment of the edge ring openings 104 and the inner pumping liner wall openings 214, resulting in there being 50% of full flow conductance.

In FIG. 4C, the edge ring 202 has been rotated 1.5 degrees to a 0% conductance or choked configuration where there is no gas flow through the pumping liner openings because the inner pumping liner wall openings 214 completely blocked by the gaps 206 in the edge ring 202. The controller 230 is utilized to control the degree of rotation of the edge ring 202, which is supported on the rotatable pedestal 112, which is rotated by the rotation motor 114.

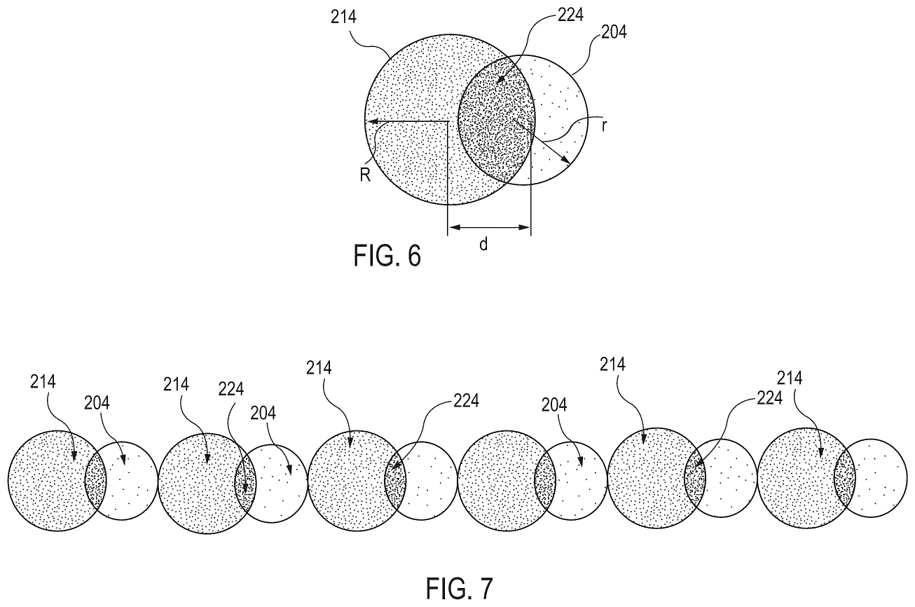

FIG. 6 shows an enlarged schematic view depicting partial overlap of an edge ring opening and an inner pumping liner opening in accordance with one or more embodiments of the disclosure, and FIG. 7 shows an enlarged schematic view depicting partial overlap of a plurality of edge ring openings and a plurality of inner pumping liner opening in accordance with one or more embodiments of the disclosure. First referring to FIG. 6, the edge ring opening 204 radius is represented by the lower case “r” and the inner pumping liner wall opening 214 radius is represented by the upper case “R.” The amount of overlap 224 of the edge ring opening 204 and the inner pumping liner wall opening 214 is represented by the distance lower case letter “d.”

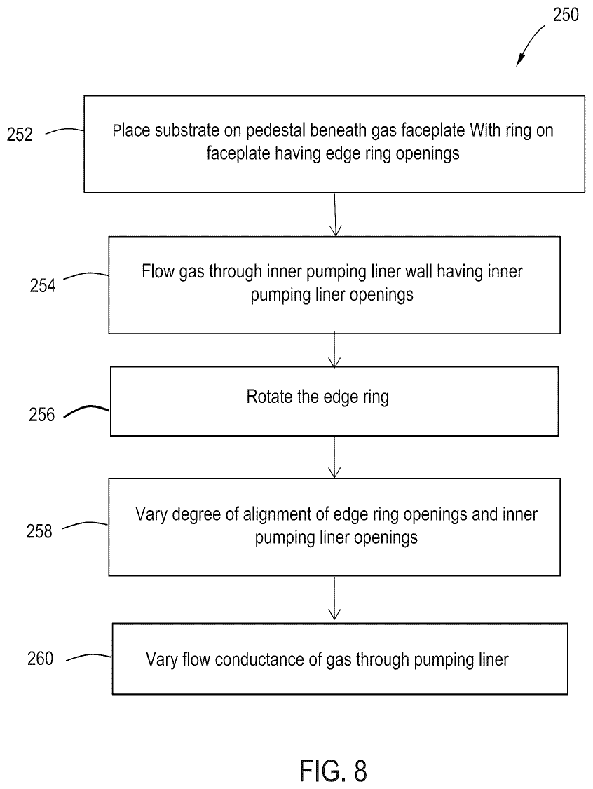

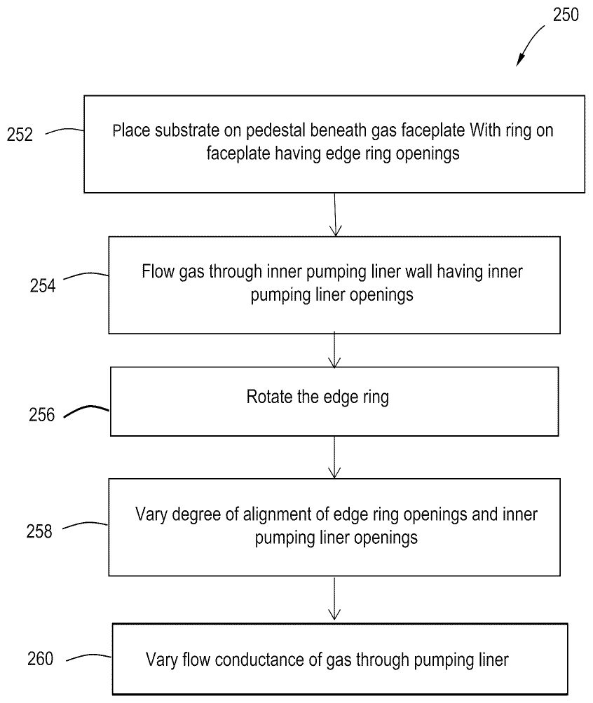

Referring now to FIG. 8, another aspect of the disclosure pertains to a method 250 of processing a substrate in a substrate processing chamber. The method 250 includes at process step 252 placing a substrate on a rotatable pedestal disposed beneath a gas distribution faceplate of the substrate processing chamber, where the rotatable pedestal having an outer peripheral portion and an edge ring having a plurality of edge ring openings disposed on the outer peripheral portion of the rotatable pedestal as described herein. At process step 254, the method includes flowing gas through an inner pumping liner including a pumping liner wall concentric with the edge ring and an outer pumping liner wall, the inner pumping liner wall and the outer pumping liner wall defining the pumping liner, the inner pumping liner wall having a plurality of inner pumping liner wall openings as described herein. At process step 256, the method includes rotating the edge ring, which at process step 258 includes varying a degree of alignment of at least a portion of the plurality of the edge openings and the plurality of inner pumping liner wall opening. This results in process step 260, varying a flow conductance of the gas through the pumping liner as described herein.

Rotating the edge ring includes rotating the rotating pedestal upon which the edge ring is supported. The method further comprises depositing a film on the substrate using a vapor deposition process. As described above, there is a range of from about 24 to about 144 edge ring openings and there is a range of from about 24 to about 144 inner pumping liner wall openings. For example, in some embodiments of the method, there are 72 edge ring openings and 72 inner pumping liner wall openings.

In a full flow conductance position, the edge ring openings and the inner pumping liner wall openings are fully aligned and there is full flow conductance through the pumping liner. The edge ring is configured to be rotated in increments of equal to or less than 2 degrees to adjust flow conductance through the pumping liner. When the edge ring is rotated 1 degree from the full flow conductance position, the flow conductance through the pumping liner reduced by 50%. When the edge ring is rotated 1.5 degrees from the full flow conductance position, the flow conductance through the pumping liner reduced by 100% and there is zero flow conductance through the pumping liner.

Advantageously, according to one or more embodiments disclosed herein, improved substrate processing chamber and methods are configured to provide a wider range of pressures at which semiconductor processing chambers can operate. Embodiments provide improved substrate processing chambers and methods that are configured to provide a more precise transition between different pressures and maintain precise target pressures during various stages of a semiconductor fabrication process. Additionally, embodiments described herein are configured provide in-situ adjustability of flow conductance through the pumping liner during CVD and ALD processes. “In-situ” refers to the gas flow distribution assembly, substrate processing chamber and method being adjustable during a CVD or ALD process without having to pause the process to make adjustments to the assembly, the method or the substrate processing chamber. Gas flow conductance can be incrementally varied in-situ under a vacuum environment. Thus, in one or more embodiments, an edge ring, a gas distribution assembly, a substrate processing chamber and a method are provided that provide improved and variable gas flow conductance through the pumping liner by providing and edge ring and inner pumping liner wall having openings that are configured to provide in situ flow conductance adjustment despite asymmetric chamber exhaust. This, in turn results in uniform distribution of the precursor across the substrate surface and the formation of uniform thin films. Non-uniform gas flow conductance through the pumping liner results in non-uniform film thickness across the substrate.

Although the disclosure herein provided a description with reference to particular embodiments, it is to be understood that these embodiments are merely illustrative of the principles and applications of the disclosure. It will be apparent to those skilled in the art that various modifications and variations can be made to the present disclosure without departing from the spirit and scope thereof. Thus, it is intended that the pre-sent disclosure include modifications and variations that are within the scope of the appended claims and their equivalents.

What is claimed is:

1. A substrate processing chamber gas distribution assembly, comprising:
a gas manifold having an inner gas channel that extends along a central axis of the gas manifold, the inner gas channel having an upper portion and a lower portion;
a backing plate coupled to the gas manifold and having a contoured bottom surface that extends downwardly and outwardly from a central opening coupled to the lower portion of the inner gas channel to a peripheral portion of the backing plate;
a gas distribution faceplate disposed below the backing plate, having a top surface and a bottom surface with a plurality of apertures extending through the gas distribution faceplate from the top surface to the bottom surface;
a rotatable pedestal disposed beneath the gas distribution faceplate and configured to support a substrate, the rotatable pedestal having an outer peripheral portion;
an edge ring disposed on the outer peripheral portion of the rotatable pedestal and configured to be rotated with the rotatable pedestal and having a plurality of edge ring openings; and
an inner pumping liner wall concentric with the edge ring and an outer pumping liner wall, the inner pumping liner wall and the outer pumping liner wall defining a pumping liner, the inner pumping liner wall having a plurality of inner pumping liner wall openings, wherein rotation of the edge ring varies a flow conductance through the pumping liner by varying a degree of alignment of at least a portion of the plurality of the edge ring openings and the plurality of inner pumping liner wall openings.

2. The substrate processing chamber gas distribution assembly of claim 1, wherein rotation of the edge ring relative to the inner pumping liner wall adjusts the flow conductance of a gas flowing through the pumping liner during a vapor deposition process.

3. The substrate processing chamber gas distribution assembly of claim 2, wherein relative rotation of the edge ring and the inner pumping liner wall enables in-situ adjustment of the flow conductance through the pumping liner during a vapor deposition process.

4. The substrate processing chamber gas distribution assembly of claim 3, wherein there is a range of from about 24 to about 144 edge ring openings and there is a range of from about 24 to about 144 inner pumping liner wall openings.

5. The substrate processing chamber gas distribution assembly of claim 4, wherein there are 72 edge ring openings and 72 inner pumping liner wall openings.

6. The substrate processing chamber gas distribution assembly of claim 3, wherein when the edge ring is in a full flow conductance position, the edge ring openings and the inner pumping liner wall openings are fully aligned.

7. The substrate processing chamber gas distribution assembly of claim 3, wherein the edge ring is configured to be rotated in increments of equal to or less than 2 degrees to adjust flow conductance through the pumping liner.

8. The substrate processing chamber gas distribution assembly of claim 6, wherein when the edge ring is rotated 1 degree from the full flow conductance position, the flow conductance through the pumping liner reduced by 50%.

9. The substrate processing chamber gas distribution assembly of claim 6, wherein when the edge ring is rotated 1.5 degrees from the full flow conductance position, the flow conductance through the pumping liner reduced by 100% and there is zero flow conductance through the pumping liner.

10. The substrate processing chamber gas distribution assembly of claim 1, wherein on a first side of the inner pumping lining wall a first group of the plurality of inner pumping liner wall openings are spaced openings and on a second side opposite the first side of the inner pumping lining wall, there is an elongate slot configured to provide asymmetric flow conductance.

11. A substrate processing chamber comprising the substrate processing chamber gas distribution assembly of claim 1.

12. A method of processing a substrate in a substrate processing chamber, the method comprising:
placing a substrate on a rotatable pedestal disposed beneath a gas distribution faceplate of the substrate processing chamber, the rotatable pedestal having an outer peripheral portion and an edge ring having a plurality of edge ring openings disposed on the outer peripheral portion of the rotatable pedestal;
flowing gas through an inner pumping liner including a pumping liner wall concentric with the edge ring and an outer pumping liner wall, the inner pumping liner wall and the outer pumping liner wall defining the pumping liner, the inner pumping liner wall having a plurality of inner pumping liner wall openings; and
rotating the edge ring to vary a flow conductance of the gas through the pumping liner by varying a degree of alignment of at least a portion of the plurality of the edge openings and the plurality of inner pumping liner wall openings.

13. The method of claim 12, wherein rotating the edge ring includes rotating the rotating pedestal.

14. The method of claim 12, further comprising depositing a film on the substrate using a vapor deposition process.

15. The method of claim 14, wherein there is a range of from about 24 to about 144 edge ring openings and there is a range of from about 24 to about 144 inner pumping liner wall openings.

16. The method of claim 14, wherein there are 72 edge ring openings and 72 inner pumping liner wall openings.

17. The method of claim 14, wherein when the edge ring is in a full flow conductance position, the edge ring openings and the inner pumping liner wall openings are fully aligned and there is full flow conductance through the pumping liner.

18. The method of claim 14, wherein the edge ring is configured to be rotated in increments of equal to or less than 2 degrees to adjust flow conductance through the pumping liner.

19. The method of claim 18, wherein when the edge ring is rotated 1 degree from the full flow conductance position, the flow conductance through the pumping liner reduced by 50%.

20. The method of claim 18, wherein when the edge ring is rotated 1.5 degrees from the full flow conductance position, the flow conductance through the pumping liner reduced by 100% and there is zero flow conductance through the pumping liner.
